(19) United States
(12) Patent Application Publication
(10) Pub. No.: US 2008/0185040 A1
(43) Pub. Date: Aug. 7, 2008

(54) Socket mounting of component in an optical system

(75) Inventors: Lawrence Tom, Sunnyvale, CA (US); Gary D. Conley, Saratoga, CA (US)

Correspondence Address: Trellis Intellectual Property Law Group, PC, 1900 EMBARCADERO ROAD, SUITE 109, PALO ALTO, CA, 94303, US

(73) Assignee: Sol Focus, Inc., Palo Alto, CA (US)

(21) Appl. No.: 11/701,601

(22) Filed: Feb. 1, 2007

(51) Int. Cl. H01L 31/00

(52) U.S. Cl. 136/259; 136/246

(57) ABSTRACT

In one embodiment, an apparatus includes a housing. The housing includes one or more units where each unit includes one or more optical elements. The optical elements are configured to concentrate electromagnetic radiation, such as light, from a larger area to a smaller focused area. The optical elements may be sealed in the housing. A removable device is included that is configured to be inserted into a unit. The removable device includes a photovoltaic cell that is configured to receive at least a portion of the concentrated electromagnetic radiation. The removable device is configured to be removable from the housing from a second side of the housing without breaking the seal on the first side of the housing. Accordingly, when the removable device needs to be removed, it can be removed without breaking the seal on the first side of the housing.

### BACKGROUND

Particular embodiments generally relate to solar power generation systems.

Solar energy has long held great promise to a solution of the world's energy problems. Solar power generation has already proven to be effective and environmentally effective. This has made the appeal of solar energy more popular.

In a solar power generation system, panels or arrays (i.e., an array of panels) of power units may be used. The solar power generation system may include a large number of power units in each panel. The power units each typically include concentrators (e.g., mirrors) and a photovoltaic cell, which are included in a housing. The cell is used to convert sunlight into electricity. The housing is typically sealed with a front window. When one of the photovoltaic cells in one of the units fails, the only way to replace the photovoltaic cell is to break the seal at the front window and remove the front window. However, breaking the front seal, replacing the photovoltaic cell, and resealing the front window is not cost effective or feasible. Instead, the whole panel is deemed scrap and replaced. Thus, the individual units are not considered to be serviceable and the otherwise operational power units in the panel are scrapped. Thus, a large cost is incurred when a single unit has a photovoltaic cell fail.

### SUMMARY

Particular embodiments generally relate to solar power generation systems that include a removable device that can be mounted in the system.

In one embodiment, an apparatus includes a housing. The housing includes one or more units where each unit includes one or more optical elements. The optical elements are configured to concentrate electromagnetic radiation, such as light, from a larger area to a smaller focused area. For example, the optical elements may be arranged in a concentrator-type arrangement, i.e., optical elements that concentrate light to a focus area. The optical elements may be sealed in the housing. For example, a front side window may be included on the housing that seals each of the units in the housing.

A removable device is included that is configured to be inserted into a unit. The removable device includes a photovoltaic cell that is configured to receive at least a portion of the concentrated electromagnetic radiation. The removable device is configured to be removable from the housing from a second side of the housing without breaking the seal on the first side of the housing. Accordingly, when the removable device needs to be removed, such as when a photovoltaic cell needs to be serviced or replaced, it can be removed without breaking the seal on the first side of the housing. This allows easy repair and does not require a large scale servicing of the entire housing.

A further understanding of the nature and the advantages of particular embodiments disclosed herein may be realized by reference to the remaining portions of the specification and the attached drawings.

### BRIEF DESCRIPTION OF THE DRAWINGS

FIG. 1 depicts a housing for a solar power generation system according to one embodiment of the present invention.

FIG. 2 shows electrical connections for a removable device according to one embodiment.

FIG. 3 shows a cutout view of the removable device according to one embodiment.

FIG. 4 depicts an example system incorporating housings according to one embodiment.

### DETAILED DESCRIPTION OF EMBODIMENTS

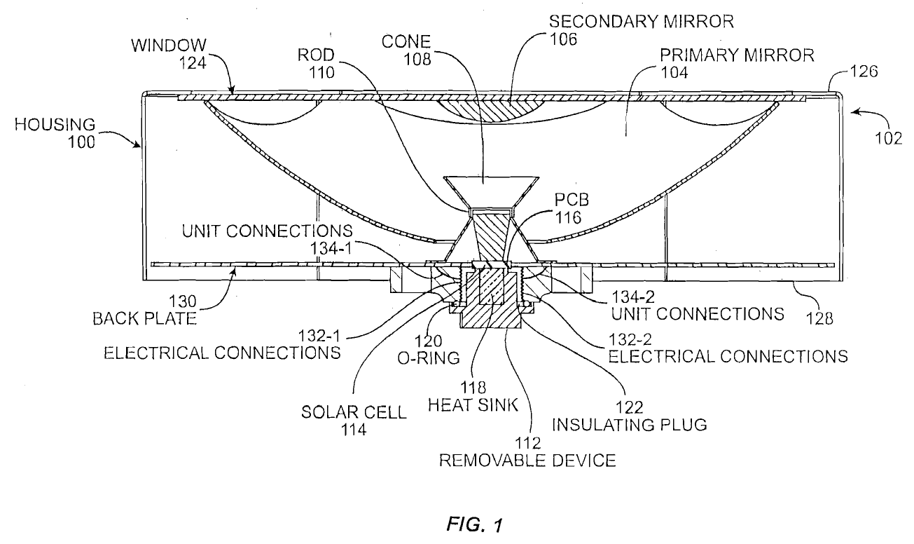

FIG. 1 depicts a housing 100 for a solar power generation system according to one embodiment of the present invention. A single unit 102 is shown in housing 100. However, it will be recognized that housing 100 may also include any number of units. Power generation system 100 may facilitate convert electromagnetic radiation, such as sunlight, light or solar radiation, to electricity. The term light will be used for discussion purposes but it will be understood that light may be any radiation.

As shown, unit 102 includes a primary optical element 104, a secondary optical element 106, a cone 108, and a rod 110. Primary optical element 104 and secondary optical element 106 may be any reflective surface. For example, optical elements 104 and 106 may be a mirror, glass, etc. In one embodiment, primary optical element 104 reflects or concentrates light to a focus area where secondary optical element 106 is substantially situated. Secondary optical element 106 may then reflect the electromagnetic radiation to a second focus area. Although two optical elements are described, it will be understood that any number of optical elements may be used.

The light may be focused into cone 108 and rod 110. Cone 108 and rod 110 then focus the light into an area where a photovoltaic cell 114 is located on removable device 112. Photovoltaic cell 114 is then configured to facilitate converting the light to electricity.

Removable device 112 is configured to be insertable into housing 100 through a second side 128. Although second side 128 is shown on the side opposite from first side 126, it will be understood that second side 128 may be on any side of housing 100. Also, removable device 112 may be inserted through first side 126.

An O ring 120 is configured to help seal removable device 112 to housing 100. For example, when removable device 112 is locked into housing 100, the O ring serves to seal removable device 112 to housing 100 when it contacts a surface of housing 100. The seal may be airtight or may allow a limited amount of air to flow into housing 100. Although O ring 120 is described, other sealing devices may be used to seal removable device 112 to housing 100.

Removable device 112 may be inserted into housing 100 and locked. For example, removable device 112 cannot be easily removed from housing 100 after being locked. An unlocking mechanism may be needed to unlock and remove removable device 112. For example, a special tool may be needed to unlock removable device 112 from housing 100, such as a key, wrench, etc.

Removable device 112 may be inserted and aligned in housing 100 using various methods. Removable device may be aligned and oriented in a proper position to receive light that is concentrated. For example, photovoltaic cell 114 may be situated below rod 110 such that light concentrated from primary optical element 104 to secondary optical element 106 into cone 108 and rod 110. The light is then received at the proper angles and orientation as desired at photovoltaic cell 114.

Removable device 112 may include threads that screw removable device 112 into housing 100. Also, removable device 112 may be pushed into housing 100 and turned to align and lock it. Further, pins may be used to lock removable device 112 in any kind of socket. It will be understood that any kind of alignment mechanism may be used to align removable device 112 into housing 100.

A locking mechanism may also be provided such that removable device 112 may not be easily removed. For example, a slot, such as a screwdriver slot, may be provided to remove removable device 112. Further, a lock, such as a key lock, may include removing locking mechanism 304.

Once inserted, removable device 112 can be removed from housing 100. In one embodiment, window 124 is sealed on a first side 126 of housing 100. The seal may be between a portion of the one or more optical elements and first side 126. Window 124 may be sealed through many methods, such as by any adhesive. In one embodiment, window 124 is sealed on a side in which sunlight is received. For example, sunlight travels through window 124 to be reflected off of primary optical element 104. It will be understood that other sealing of surfaces may be appreciated, such as the sealing of the sides of housing 100. For example, first side 126 may be sealed with second side 128.

Removable device 112 may be removed from unit 102 without breaking the seal of window 124 on first side 126 (or any seal of any other surface other than the area that removable device 112 is in contact with). Thus, service to parts included on removable device 112 may be performed without breaking the seal on first side 126. For example, photovoltaic cell 114 may be serviced if a problem occurs. In one example, if photovoltaic cell fails and needs to be replaced, then removable device 112 may be removed from unit 102 and photovoltaic cell 114 may be replaced. Then, removable device 112 may be reinserted into unit 102.

Photovoltaic cell 114 may be the most likely item to fail in unit 102. Thus, being able to replace photovoltaic cell 114 easily is useful. Although replacement of photovoltaic cell 114 is discussed, it will be recognized that servicing of any part of unit 102 may be performed by removing removable device 112. For example, access to parts in unit 102 is allowed when removable device 112 is removed from unit 102.

Accordingly, a process for replacing photovoltaic cells (or any other component of removable device 112) is provided. The process does not break the seal of window 124 on first side 126 and thus the servicing is not labor-intensive and costly. Removable device 112 can easily be removed from unit 102 and be reinserted.

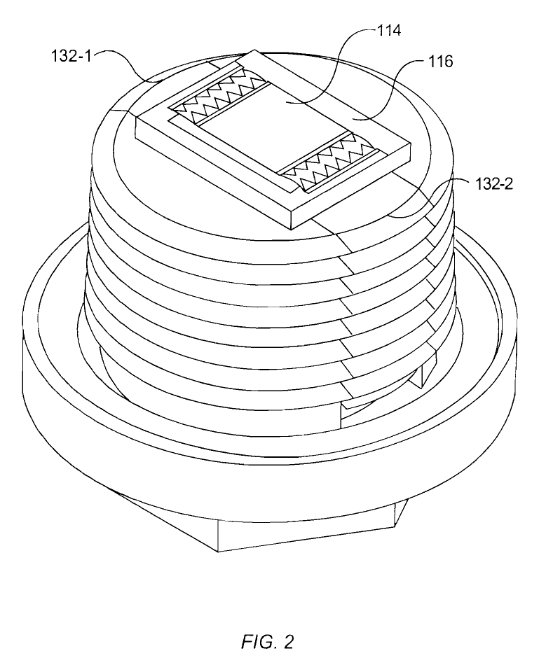

FIG. 2 shows electrical connections 132 for removable device 112 according to one embodiment. Printed circuit board 116 may include photovoltaic cell 114. Printed circuit board 116 provides connections to other components that facilitate converting light into electricity. A person skilled in the art will appreciate components that may be included on printed circuit board 116.

Electrical connections 132 provide electrical contact between photovoltaic cell and unit 102. For example, electrical connection 132-1 may be connected to back plate 130. Back plate 130 may be coupled to a number of units 102 and conducts electricity to a central power system. The central power system may store the electricity or transfer it to another location.

Electrical connection 132-1 may be connected to a positive connection and electrical connection 132-1 may be connected to a negative connection or ground. In one embodiment, electrical connection 132-2 is coupled to the bottom of photovoltaic cell 114 and electrical connection 132-1 is coupled to the top of the photovoltaic cell. In this case, a top of photovoltaic cell 114 is the positive connection and the bottom of photovoltaic cell 114 is the negative connection.

In one example, when removable device 112 is inserted into housing 100, electrical connections 132 are automatically coupled to photovoltaic cell 114. For example, when removable device 112 is locked into place, electrical connections 132 are automatically coupled to photovoltaic cell 114. Referring back to FIG. 1, unit connections 134 may contact electrical connections 132 when removable device 112 is inserted into housing 100. Unit connections 134 may connect to back plate 130 and a ground.

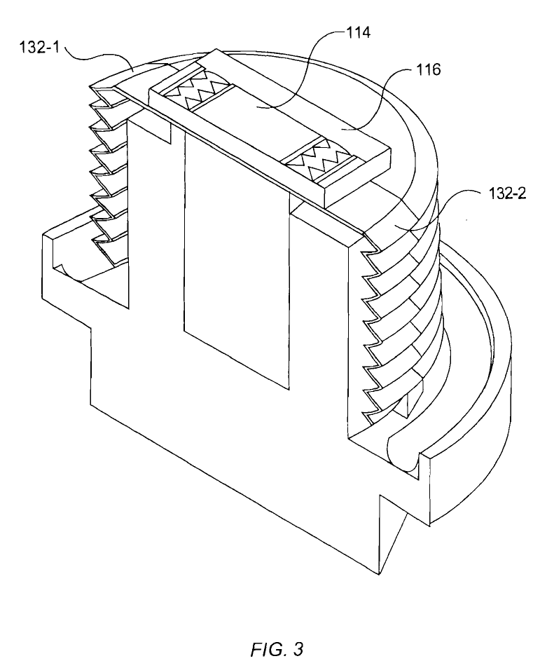

FIG. 3 shows a cutout view of removable device 112 according to one embodiment. Removable device 112 may include an insulating plug 122 that includes heat sink 118. Heat sink 118 may be any substance that may dissipate heat. For example, heat sink 118 may be a copper slug that dissipates heat away from photovoltaic cell 114. Dissipating heat may be important because, when sunlight is focused into a small area where photovoltaic cell 114 resides, a large amount of heat may be generated. Heat sink 118 dissipates some of this heat away from photovoltaic cell 114.

Insulating plug 122 may be a nonelectrically conducting material, such as plastic, ceramic, etc., but may be able to conduct heat. Insulating plug 122 surrounds heat sink 118. This ensures that electrical current is not conducted through the insulating plug 122 to heat sink 118 and/or photovoltaic cell 114.

Accordingly, the particular embodiments provide many advantages. For example, photovoltaic cell 114 may be individually replaced from solar power generation systems. This may be useful when the solar power generation systems include multiple units 102. Thus, there is a larger chance that one photovoltaic cell 114 may fail or need to be serviced in the system. Thus, by having a convenient way to remove photovoltaic cell 114 from housing 100, servicing is cost-efficient and easy. Also, a whole panel does not need to be discarded when one photovoltaic cell 114 in a unit fails.

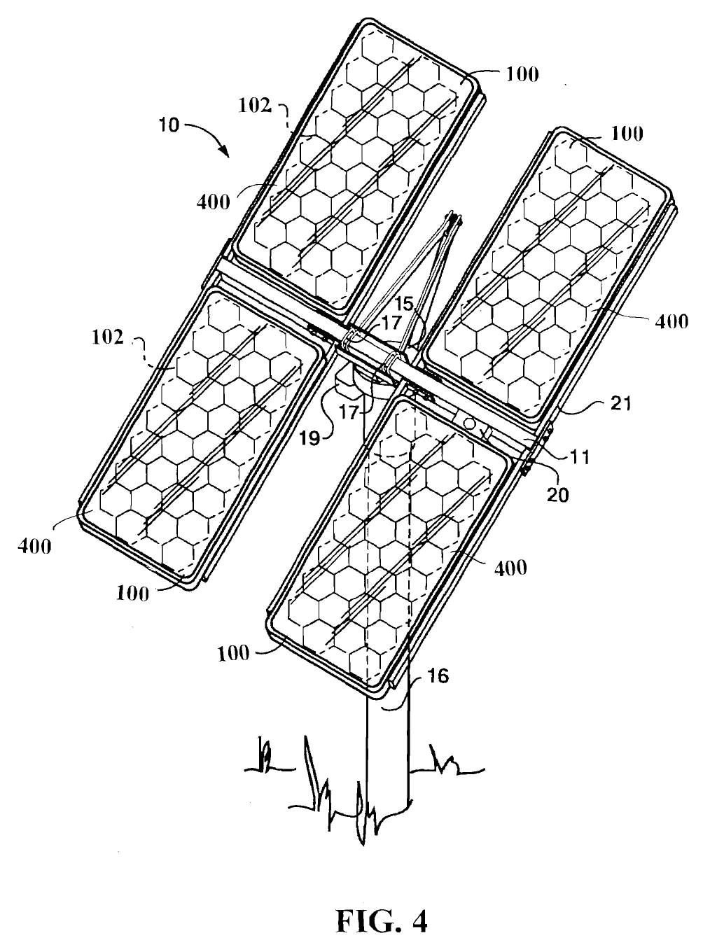

FIG. 4 depicts an example system incorporating one or more housings 100 according to one embodiment. An array 10 that includes a plurality of solar housings 100 provided in a substantially planar configuration. In the example of FIG. 4, four solar housings 100 collectively form array 10, but it should be appreciated that any number of solar housings may be employed, from a single solar housing to many more than four housings. Each housing 100 houses a matrix of power units 102 that convert sunlight, or solar radiation, to electricity. In the exemplary illustration of FIG. 4, thirty-two power units 102 are shown in each solar housing 12, although this depiction should not be unnecessarily limiting to the present subject matter. A fewer or greater number of power units may be provided in each solar housing, and such power units may be provided in a variety of particular configurations. Each power unit has a mechanical arrangement which focuses solar energy to an optical rod, which conducts it to a single photovoltaic (PV) cell. These and other particular aspects of the power units will be described later in more detail.

In one embodiment, each housing 12 of array 10 measures approximately one meter by two meters and is provided with a relatively compact depth of about 10 cm, due in part to the efficiency of the optical components of each power unit. A collective assembly of four housings as depicted in FIG. 4 may form a substantially rectangular shape measuring about 2.25 meters by 4.25 meters and also characterized by a depth of 10 cm. A depth of between about two and thirty cm is generally provided in some of the disclosed exemplary embodiments. These dimensions are provided for example only and should not be limiting to the present subject matter.

As shown, a front window 400 is sealed with housing 100. Front window 400 covers multiple power units 102 in a single housing 100.

The array 10 of FIG. 4 is positioned atop a mounting pole 16, which in some embodiments may be about 2.5 meters tall. A structural frame 21 is provided along the array 10 to help maintain planarity and rigidity of the assembly. Structural frame 21 is connected to a torque bar 11 that serves to rotate the assembly of solar housings 100 about its center in two axes: a front-back axis and a left-right axis. A motorized gear drive assembly 15 provided at the top of mounting pole 16 is coupled to torque bar 11 via pivot point connections 17. Gear drive assembly 15 is also coupled to a controller 19, which may correspond to a microcontroller in some embodiments. Gear drive assembly 15, controller 19, torque bar 11 and mounting pole 16 all combine to form a tracker for the solar housing array.

The tracker components illustrated in FIG. 4 collectively function to orient the respective power units 102 in optimum direction for receiving sunlight such that the PV cells therein can operate most effectively. The motorized gear assembly 15 is operated by controller 19 based on input received from a narrow range sun sensor 20 that provides accurate pointing information. In one embodiment, sun sensor 20 operates over a range of about five degrees, and is used to zero array 10 to the sun for large pointing errors. In some embodiments, sun sensor 20 is not required, such as instances where the array is generally positioned within the capture angle of certain optical components of the power units.

It should be appreciated that many other array and tracker configurations are applicable for use with the presently disclosed technology, including but not limited to ganged arrays of housings for a low profile roof mount application. Such arrays could be equatorial mounted and polar aligned so as to allow near-single axis tracking. These too could be configured to park in a downward facing position each evening or during other predetermined conditions to minimize environmental particulate accumulation and to afford further protection to the system.

Although the description has been described with respect to particular embodiments thereof, these particular embodiments are merely illustrative, and not restrictive. Although solar optical elements are discussed, it will be understood that other optical elements may be used.

Any suitable programming language can be used to implement the routines of particular embodiments including C, C++, Java, assembly language, etc. Different programming techniques can be employed such as procedural or object oriented. The routines can execute on a single processing device or multiple processors. Although the steps, operations, or computations may be presented in a specific order, this order may be changed in different particular embodiments. In some particular embodiments, multiple steps shown as sequential in this specification can be performed at the same time. The sequence of operations described herein can be interrupted, suspended, or otherwise controlled by another process, such as an operating system, kernel, etc. The routines can operate in an operating system environment or as stand-alone routines occupying all, or a substantial part, of the system processing. Functions can be performed in hardware, software, or a combination of both. Unless otherwise stated, functions may also be performed manually, in whole or in part.

In the description herein, numerous specific details are provided, such as examples of components and/or methods, to provide a thorough understanding of particular embodiments. One skilled in the relevant art will recognize, however, that a particular embodiment can be practiced without one or more of the specific details, or with other apparatus, systems, assemblies, methods, components, materials, parts, and/or the like. In other instances, well-known structures, materials, or operations are not specifically shown or described in detail to avoid obscuring aspects of particular embodiments.

A “computer-readable medium” for purposes of particular embodiments may be any medium that can contain, store, communicate, propagate, or transport the program for use by or in connection with the instruction execution system, apparatus, system, or device. The computer readable medium can be, by way of example only but not by limitation, an electronic, magnetic, optical, electromagnetic, infrared, or semiconductor system, apparatus, system, device, propagation medium, or computer memory.

Particular embodiments can be implemented in the form of control logic in software or hardware or a combination of both. The control logic, when executed by one or more processors, may be operable to perform that what is described in particular embodiments.

A “processor” or “process” includes any human, hardware and/or software system, mechanism or component that processes data, signals, or other information. A processor can include a system with a general-purpose central processing unit, multiple processing units, dedicated circuitry for achieving functionality, or other systems. Processing need not be limited to a geographic location, or have temporal limitations. For example, a processor can perform its functions in “real time,” “offline,” in a “batch mode,” etc. Portions of processing can be performed at different times and at different locations, by; different (or the same) processing systems.

Reference throughout this specification to “one embodiment”, “an embodiment”, “a specific embodiment”, or “particular embodiment” means that a particular feature, structure, or characteristic described in connection with the particular embodiment is included in at least one embodiment and not necessarily in all particular embodiments. Thus, respective appearances of the phrases “in a particular embodiment”, “in an embodiment”, or “in a specific embodiment” in various places throughout this specification are not necessarily referring to the same embodiment. Furthermore, the particular features, structures, or characteristics of any specific embodiment may be combined in any suitable manner with one or more other particular embodiments. It is to be understood that other variations and modifications of the particular embodiments described and illustrated herein are possible in light of the teachings herein and are to be considered as part of the spirit and scope.

Particular embodiments may be implemented by using a programmed general purpose digital computer, by using application specific integrated circuits, programmable logic devices, field programmable gate arrays, optical, chemical, biological, quantum or nanoengineered systems, components and mechanisms may be used. In general, the functions of particular embodiments can be achieved by any means as is known in the art. Distributed, networked systems, components, and/or circuits can be used. Communication, or transfer, of data may be wired, wireless, or by any other means.

It will also be appreciated that one or more of the elements depicted in the drawings/figures can also be implemented in a more separated or integrated manner, or even removed or rendered as inoperable in certain cases, as is useful in accordance with a particular application. It is also within the spirit and scope to implement a program or code that can be stored in a machine-readable medium to permit a computer to perform any of the methods described above.

Additionally, any signal arrows in the drawings/Figures should be considered only as exemplary, and not limiting, unless otherwise specifically noted. Furthermore, the term “or” as used herein is generally intended to mean “and/or” unless otherwise indicated. Combinations of components or steps will also be considered as being noted, where terminology is foreseen as rendering the ability to separate or combine is unclear.

As used in the description herein and throughout the claims that follow, “a”, “an”, and “the” includes plural references unless the context clearly dictates otherwise. Also, as used in the description herein and throughout the claims that follow, the meaning of “in” includes “in” and “on” unless the context clearly dictates otherwise.

The foregoing description of illustrated particular embodiments, including what is described in the Abstract, is not intended to be exhaustive or to limit the invention to the precise forms disclosed herein. While specific particular embodiments of, and examples for, the invention are described herein for illustrative purposes only, various equivalent modifications are possible within the spirit and scope, as those skilled in the relevant art will recognize and appreciate. As indicated, these modifications may be made to the present invention in light of the foregoing description of illustrated particular embodiments and are to be included within the spirit and scope.

Thus, while the present invention has been described herein with reference to particular embodiments thereof, a latitude of modification, various changes and substitutions are intended in the foregoing disclosures, and it will be appreciated that in some instances some features of particular embodiments will be employed without a corresponding use of other features without departing from the scope and spirit as set forth. Therefore, many modifications may be made to adapt a particular situation or material to the essential scope and spirit. It is intended that the invention not be limited to the particular terms used in following claims and/or to the particular embodiment disclosed as the best mode contemplated for carrying out this invention, but that the invention will include any and all particular embodiments and equivalents falling within the scope of the appended claims.

We claim:

1. A system comprising:
a housing comprising a unit including one or more optical elements configured to concentrate electromagnetic radiation, the one or more optical elements being sealed in the housing on a first side; and
a removable device configured to be inserted into the unit, the removable device comprising a photovoltaic cell configured to receive at least a portion of the concentrated electromagnetic radiation, the removable device configured to be removable from the housing from a second side without breaking the seal on the first side of the housing.

2. The system of claim 1, wherein the removable device comprises one or more electrical connections configured to couple to the housing when the removable device is inserted into the unit.

3. The system of claim 2, wherein the one or more electrical connections are automatically coupled to one or more unit connections of the housing upon the removable device being inserted into the unit.

4. The system of claim 1, wherein the photovoltaic cell is automatically aligned to receive the electromagnetic radiation upon inserting the removable device into the unit.

5. The system of claim 1, wherein the removable device comprises a heat sink configured to dissipate heat away from the photovoltaic cell.

6. The system of claim 1, wherein the removable device comprises a sealing device configured to seal at least a portion of the second side of the housing upon insertion of the removable device into the unit.

7. The system of claim 1, wherein the seal in the housing on the first side is between a portion of the one or more optical elements and the first side.

8. The system of claim 1, wherein the electromagnetic radiation is light.

9. The system of claim 1, wherein the first side and the second side are sealed together.

10. The system of claim 1, further comprising a plurality of removable devices, each removable device configured to be inserted into the unit, the removable device comprising a photovoltaic cell configured to receive at least a portion of the concentrated electromagnetic radiation, each removable device configured to be removable from the housing from a second side without breaking the seal on the first side of the housing.

11. A removable device for a solar power generation system, the removable device comprising:
a photovoltaic cell configured to convert radiation into electricity when radiation is received from one or more optical elements sealed in a unit of a housing on a first side of the solar power generation system; and
a plug configured to hold the photovoltaic cell, wherein the plug is configured to be inserted into the unit, the plug configured to be removable from the housing from a second side without breaking the seal on the first side of the housing.

12. The removable device of claim 11, further comprising one or more electrical connections configured to couple to the housing when the removable device is inserted into the unit.

13. The removable device of claim 12, wherein the one or more electrical connections are automatically coupled to one or more unit connections of the housing upon the removable device being inserted into the unit.

14. The removable device of claim 11, wherein the photovoltaic cell is automatically aligned to receive the electromagnetic radiation upon inserting the removable device into the unit.

15. The removable device of claim 11, further comprising a heat sink configured to dissipate heat away from the photovoltaic cell.

15. The removable device of claim 11, further comprising a sealing device configured to seal at least a portion of the second side of the housing upon insertion of the removable device into the unit.

16. The removable device of claim 11, wherein the seal in the housing on the first side is between a portion of the one or more optical elements and the first side.

17. The removable device of claim 11, wherein the electromagnetic radiation is light.

18. The removable device of claim 11, wherein the first side and the second side are sealed together.

19. A method comprising:
providing a housing, the housing comprising a unit including one or more optical elements configured to concentrate electromagnetic radiation, the one or more optical elements being sealed in the housing on a first side; and
inserting a removable device into the unit, the removable device comprising a photovoltaic cell configured to receive at least a portion of the concentrated electromagnetic radiation, the removable device configured to be removable from the housing from a second side without breaking the seal on the first side of the housing.

20. The method of claim 19, wherein the photovoltaic cell is automatically aligned to receive the electromagnetic radiation upon inserting the removable device into the unit.

21. The method of claim 19, further comprising sealing the removable device to the unit using a sealing device configured to seal at least a portion of the second side of the housing upon insertion of the removable device into the unit.

22. The method of claim 19, wherein the seal in the housing on the first side is between a portion of the one or more optical elements and the first side.

23. The method of claim 19, sealing the first side and the second side together.

24. The method of claim 19, wherein one or more electrical connections of the removable device are automatically coupled to one or more unit connections of the housing upon the removable device being inserted into the unit.

25. The method of claim 19, wherein the photovoltaic cell is automatically aligned to receive the electromagnetic radiation upon inserting the removable device into the unit.
